(19) United States
(12) Patent Application Publication
(10) Pub. No.: US 2026/0245491 A1
(43) Pub. Date: Aug. 20, 2026

(54) DISPLAY DRIVER CHIP AND DISPLAY MODULE

(71) Applicant: Novatek Microelectronics Corp., Hsinchu (TW)

(72) Inventor: Yu-Jen Yen, Tainan City (TW)

(73) Assignee: Novatek Microelectronics Corp., Hsinchu (TW)

(21) Appl. No.: 19/207,277

(22) Filed: May 13, 2025

(30) Foreign Application Priority Data
Feb. 14, 2025 (TW) 114105533

(51) Int. Cl. G09G 3/20; H10D 86/40

(52) U.S. Cl. CPC G09G 3/2092; H10D 86/441; G09G 2310/0286; G09G 2380/10

(57) ABSTRACT

The present disclosure provides a display driving IC and a display module comprising the display driving IC. The display driving IC includes: a plurality of metal bumps arranged along a first boundary; and a data processing circuit for receiving multiple display data. The data processing circuit divides the plurality of chip signal channels into multiple groups of chip signal channels, employs an opposite connection state to connect to corresponding groups of panel signal channels, and controls the filling sequence of the display data based on the connection state. Through this design, the present disclosure achieves a slim bezel effect while avoiding the metal layer resource consumption problems associated with traditional lower bump schemes, and simplifies part number management through a standardized bump structure and configuration, thereby improving production efficiency.

### CROSS-REFERENCE TO RELATED APPLICATION

This application claims the priority benefit of Taiwan application serial no. 114105533 filed on Feb. 14, 2025. The entirety of the above-mentioned patent application is hereby incorporated by reference herein and made a part of this specification.

### BACKGROUND

### Technical Field

The present disclosure relates to a display driving technology field, and more particularly to a display driver and a display module having the display driver.

### Description of Related Art

With the development of vehicle display technology, floating-type vehicle interior displays (CID) and digital rearview mirrors have become increasingly common. These applications have higher requirements for slim bezel design of display modules. Currently, there are two main technical solutions for implementing slim bezel design: one is using Chip On Film (COF) technology, and the other is using Chip On Glass (COG) technology with recessed bumps.

Among them, although COF technology can achieve slim bezel effect, its manufacturing cost is relatively high. While the COG solution with recessed bumps can reduce cost, it has two main disadvantages: First, since the recessed bumps need to use a metal layer to achieve bump connection fan-out, this reduces the available metal routing resources in this area. Second, driver ICs using recessed bumps cannot share part numbers with driver ICs using traditional bumps, requiring additional part number management, which increases the complexity of production management.

Therefore, how to achieve slim bezel design while reducing cost, and overcome the metal layer resource limitations and part number management issues in existing technology, has become a technical problem urgently needing to be solved in this field.

### SUMMARY

In view of the above problems, the present disclosure provides a display driver and a display module having the display driver. The technical solution of the present disclosure achieves slim bezel effect through special signal channel grouping and data filling control mechanism while maintaining traditional bump structure.

One or more embodiments of the present disclosure provide a display driver adapted for driving a pixel array of a display module. The display driver includes: a plurality of metal bumps, disposed at a first boundary of the display driver, wherein the plurality of metal bumps respectively correspond to a plurality of chip signal channels of the display driver, and wherein the plurality of metal bumps are respectively electrically connected to a plurality of panel signal channels of the pixel array through a plurality of source lines; a data processing circuit, configured to receive a plurality of display data, wherein the data processing circuit is further configured to divide the plurality of chip signal channels into at least a plurality of chip signal channel groups, wherein the plurality of chip signal channel groups include at least one first chip signal channel group and at least one second chip signal channel group, wherein the at least one first chip signal channel group and the at least one second chip signal channel group respectively correspond to at least one first panel signal channel group and at least one second panel signal channel group among a plurality of panel signal channel groups, wherein each panel signal channel group includes a plurality of panel signal channels, wherein a plurality of first chip signal channels in each first chip signal channel group are connected to a plurality of first panel signal channels in the corresponding first panel signal channel group in a first connection pattern, wherein a plurality of second chip signal channels in each second chip signal channel group are connected to a plurality of second panel signal channels in the corresponding second panel signal channel group in a second connection pattern, wherein the first connection pattern and the second connection pattern are opposite to each other, wherein the data processing circuit is further configured to control an order of filling the plurality of display data into the plurality of chip signal channels based on the first connection pattern and the second connection pattern.

In an embodiment of the present disclosure, wherein the first connection pattern refers to that an (i+1)th first chip signal channel in each first chip signal channel group is connected to an (i+1)th first panel signal channel in the corresponding first panel signal channel group, wherein i is an integer from 0 to N−1, and N is a total number of the plurality of first chip signal channels in the first chip signal channel group, wherein the second connection pattern refers to that an (M−j)th second chip signal channel in each second chip signal channel group is connected to a (j+1)th second panel signal channel in the corresponding second panel signal channel group, wherein j is an integer from 0 to M−1, and M is a total number of the plurality of second chip signal channels in the second chip signal channel group.

In an embodiment of the present disclosure, the data processing circuit includes: a shift register, configured to temporarily store the plurality of display data; and a driving control circuit, electrically connected to the shift register, configured to control filling the plurality of display data from the shift register into the plurality of chip signal channels based on the first connection pattern and the second connection pattern.

In an embodiment of the present disclosure, the driving control circuit is further configured to: sequentially fill N pieces of first display data corresponding to each first chip signal channel group into a first to an Nth first chip signal channel in the first chip signal channel group; and sequentially fill M pieces of second display data corresponding to each second chip signal channel group into an Mth to a first second chip signal channel in the second chip signal channel group.

In an embodiment of the present disclosure, the data processing circuit further includes: a timing controller, electrically connected to the driving control circuit, configured to adjust an arrangement order of M pieces of second display data corresponding to each second chip signal channel group before the plurality of display data are input to the plurality of chip signal channels.

In an embodiment of the present disclosure, the timing controller is further configured to: perform reverse sorting on the M pieces of second display data from a first to an Mth piece of second display data among the M pieces of second display data corresponding to each second chip signal channel group, so as to obtain M pieces of adjusted second display data.

In an embodiment of the present disclosure, the driving control circuit is further configured to: sequentially fill N pieces of first display data corresponding to each first chip signal channel group into a first to an Nth first chip signal channel in the first chip signal channel group; and sequentially fill the M pieces of adjusted second display data corresponding to each second chip signal channel group into a first to an Mth second chip signal channel in the second chip signal channel group.

In an embodiment of the present disclosure, the display module has a glass substrate, and the pixel array and the plurality of source lines are formed on the glass substrate.

In an embodiment of the present disclosure, the driving control circuit is further configured to: apply a delay time to each first chip signal channel group, so as to form a continuous driving timing between a first signal driving time curve of the first chip signal channel group and a second signal driving time curve of an adjacent second chip signal channel group.

In an embodiment of the present disclosure, the driving control circuit is further configured to: detect a signal driving time difference between the first signal driving time curve of the first chip signal channel group and the second signal driving time curve of the adjacent second chip signal channel group; and according to the signal driving time difference, apply the delay time to a plurality of first display data output by the plurality of first chip signal channels of the first chip signal channel group, so as to form a continuous driving timing between a delayed first signal driving time curve and the second signal driving time curve.

One or more embodiments of the present disclosure provide a display module, including: a pixel array; a plurality of panel signal channels, formed on a glass substrate, wherein the pixel array is electrically connected to the plurality of panel signal channels; and a display driver. The display driver includes: a plurality of metal bumps, disposed at a first boundary of the display driver, wherein the plurality of metal bumps respectively correspond to a plurality of chip signal channels of the display driver, and wherein the plurality of metal bumps are respectively electrically connected to the plurality of panel signal channels through a plurality of source lines; and a data processing circuit, configured to receive a plurality of display data. The data processing circuit is further configured to divide the plurality of chip signal channels into at least a plurality of chip signal channel groups, the plurality of chip signal channel groups include at least one first chip signal channel group and at least one second chip signal channel group, wherein the at least one first chip signal channel group and the at least one second chip signal channel group respectively correspond to at least one first panel signal channel group and at least one second panel signal channel group among a plurality of panel signal channel groups, wherein each panel signal channel group includes a plurality of panel signal channels, wherein a plurality of first chip signal channels in each first chip signal channel group are connected to a plurality of first panel signal channels in the corresponding first panel signal channel group in a first connection pattern, wherein a plurality of second chip signal channels in each second chip signal channel group are connected to a plurality of second panel signal channels in the corresponding second panel signal channel group in a second connection pattern, wherein the first connection pattern and the second connection pattern are opposite to each other, wherein the data processing circuit is further configured to control an order of filling the plurality of display data into the plurality of chip signal channels based on the first connection pattern and the second connection pattern.

Based on the above, the display driver and display module provided by the present disclosure can achieve slim bezel effect while avoiding additional metal layer resource consumption by dividing multiple chip signal channels into multiple chip signal channel groups and adopting opposite connection patterns. Specifically, the solution of the present disclosure does not need to use recessed bumps for fan-out routing, thereby preserving complete metal layer resources and improving the routing flexibility of the chip. Furthermore, through the special design of the data processing circuit, the present disclosure achieves flexible control over the filling order of display data. This control mechanism ensures that display data can correctly correspond to target pixel positions under different connection patterns, thereby maintaining display quality. In particular, since the present disclosure adopts a standard bump structure, the same driver IC can be applied to products with both traditional bezel and slim bezel, significantly simplifying product part number management and improving production efficiency. Meanwhile, through precise control of driving timing and delay compensation mechanism, the present disclosure effectively solves the driving timing discontinuity problem between different channel groups, ensuring the uniformity of the display screen.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a block diagram illustrating a basic architecture of a display module according to an embodiment of the present disclosure.

FIG. 2 is a schematic diagram illustrating an internal architecture of a display driver according to an embodiment of the present disclosure.

FIG. 3A is a schematic diagram illustrating a wiring layout of a traditional display module.

FIG. 3B is a schematic diagram illustrating a wiring layout of a display module with recessed bump design.

FIG. 3C is a schematic diagram illustrating a wiring layout of a display module according to an embodiment of the present disclosure.

FIG. 4 is a flowchart illustrating a signal channel grouping and data processing method according to an embodiment of the present disclosure.

FIG. 5 is a schematic diagram illustrating connection patterns between chip signal channels and panel signal channels according to an embodiment of the present disclosure.

FIG. 6 is a schematic diagram illustrating a first type of data filling order according to an embodiment of the present disclosure.

FIG. 7 is a schematic diagram illustrating a second type of data filling order according to an embodiment of the present disclosure.

FIG. 8A is a schematic diagram illustrating a front-back exchange order for multiple chip signal channel groups according to an embodiment of the present disclosure.

FIG. 8B is a schematic diagram illustrating a data filling order according to an embodiment of the present disclosure.

FIG. 9A is a schematic diagram illustrating traditional signal driving time curves.

FIG. 9B is a schematic diagram illustrating the measurement of signal driving time differences according to an embodiment of the present disclosure.

FIG. 9C is a schematic diagram illustrating signal driving time curves after delay compensation according to an embodiment of the present disclosure.

### DESCRIPTION OF THE EMBODIMENTS

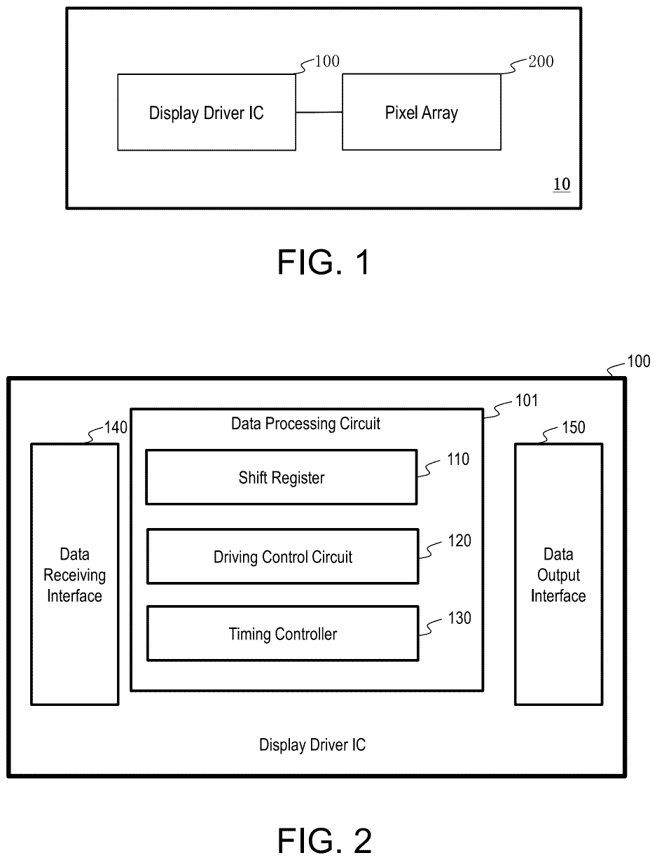

FIG. 1 is a block diagram illustrating a basic architecture of a display module according to an embodiment of the present disclosure.

Referring to FIG. 1, in an embodiment, the present disclosure provides a display module 10, which includes a display driver 100 and a pixel array 200. The display driver 100 is used for driving the pixel array 200. In the present specification, the “display module” can be understood as a display device, which includes a pixel array for displaying images, a driving chip for driving the pixel array, and a conductive structure connecting the pixel array and the driving chip. The display device can be a liquid crystal display (LCD), an organic light-emitting diode display (OLED display), or other suitable display devices.

Specifically, the display driver 100 has a plurality of metal bumps, disposed at a first boundary of the display driver 100, wherein the plurality of metal bumps respectively correspond to a plurality of chip signal channels of the display driver 100, and the plurality of metal bumps are respectively electrically connected to a plurality of panel signal channels of the pixel array 200 through a plurality of source lines. The pixel array 200 is used for receiving and displaying the display data transmitted by the display driver 100.

In this embodiment, the display driver 100 is mainly responsible for receiving and processing display data from external sources (such as application processors), and according to the control logic set by the internal data processing circuit, distributing data to each chip signal channel according to predetermined connection patterns. Through the plurality of metal bumps located at the first boundary of the chip, the IC 100 can achieve precise electrical connection with the panel signal channels on the pixel array 200, thereby driving each sub-pixel unit to correctly display corresponding image information. The chip simultaneously integrates a shift register, driving control circuit, and timing controller, ensuring the continuity of data filling order and transmission timing, effectively solving problems such as uneven brightness or wide bezel caused by inconsistent driving timing in traditional driving technology, further achieving the technical effects of slim bezel and high-resolution display.

In an embodiment, the pixel array 200 is a sub-pixel array manufactured on a glass substrate using thin-film technology, with its main function being to receive and present the display data output by the display driver 100. Specifically, the pixel array 200 includes multiple pixel units arranged in horizontal and vertical directions, with each pixel unit containing at least one light-emitting element (such as liquid crystal display or organic light-emitting diode elements) and corresponding electrode structures. Meanwhile, the panel signal channels are formed on the glass substrate in the same layer as the pixel structure, and these panel signal channels are electrically connected to the display driver 100 through source lines for transmitting driving signals, enabling each pixel to perform correct light output according to the input display data.

In an embodiment, the display module 10 is formed on a glass substrate, wherein the pixel array 200 and the plurality of source lines are formed on the glass substrate.

In an embodiment, the manufacturing method of the display module 10 involves structure fabrication on the glass substrate. Specifically, the glass substrate first undergoes pre-cleaning treatment, followed by thin-film transistor array process to form the basic structure of the pixel array 200. On the glass substrate, multiple layers including gate metal layer, insulation layer, semiconductor layer, and source/drain metal layer are formed sequentially to construct the driving circuit of the pixel array 200.

In an embodiment, the formation process of the source lines is completed during the source/drain metal layer process. Specifically, the plurality of source lines are constructed of conductive materials, such as aluminum, copper, or their alloys, and are electrically connected to the source electrodes of the thin-film transistors in the pixel array 200. One end of the plurality of source lines extends to the edge region of the glass substrate, forming a bonding area corresponding to the metal bumps of the display driver 100. In the edge region of the glass substrate, a bonding area for mounting the display driver 100 is formed. This bonding area includes multiple bonding pads for electrical connection with the metal bumps of the display driver 100. The end portions of the plurality of source lines are respectively connected to these bonding pads to establish electrical connection paths between the pixel array 200 and the display driver 100.

In an embodiment, the display module 10 can be applied to vehicle display devices, such as floating-type vehicle interior displays (CID) or digital rearview mirrors. In such application scenarios, the slim bezel design of the display module 10 can enhance overall visual effect and installation flexibility. Specifically, the display driver 100 adopts special signal channel grouping and data filling control mechanism, enabling the display module 10 to achieve slim bezel effect equivalent to recessed bump design while maintaining traditional bump structure. Through this design, the display module 10 not only maintains lower manufacturing costs but also avoids additional metal layer resource consumption.

FIG. 2 is a schematic diagram illustrating an internal architecture of a display driver according to an embodiment of the present disclosure.

Referring to FIG. 2, in an embodiment, the display driver 100 includes a data processing circuit 101, wherein the data processing circuit 101 includes: a data receiving interface 140, a data output interface 150, a shift register 110, a driving control circuit 120, and a timing controller 130.

Specifically, the data receiving interface 140 is used for receiving a plurality of display data for driving the pixel array 200. The plurality of display data may include color information, brightness information, and control information. After receiving these display data, the data receiving interface 140 will perform data format conversion and preliminary processing, and then transmit the processed data to the data processing circuit 101. In the data processing circuit 101, these display data will undergo further processing according to preset data processing procedures.

The shift register 110 is used for temporarily storing the plurality of display data, and according to control signals from the driving control circuit 120, sequentially filling the display data into the plurality of chip signal channels.

The driving control circuit 120 realizes data correspondence with the plurality of panel signal channels by controlling the data filling order of the plurality of chip signal channels. Specifically, the plurality of metal bumps are disposed at the first boundary of the display driver 100, each metal bump corresponds to one chip signal channel, and is electrically connected to the corresponding panel signal channel through a source line. By adopting different connection patterns, the data filling order in some regions is opposite to the order of panel signal channels, thereby achieving slim bezel design.

The timing controller 130 is electrically connected to the driving control circuit 120, used for adjusting the arrangement order of M pieces of second display data corresponding to each second chip signal channel group before the plurality of display data are input to the plurality of chip signal channels. Specifically, the timing controller 130 can perform reverse sorting on the M pieces of second display data to obtain M pieces of adjusted second display data.

The data output interface 150 is used for outputting the processed display data to the plurality of panel signal channels through the plurality of chip signal channels. Furthermore, the data output interface 150 further includes the plurality of metal bumps disposed at the first boundary of the display driver 100 and their corresponding plurality of chip signal channels. Each metal bump and its corresponding chip signal channel together form an output port, which is electrically connected to the panel signal channels through source lines, thereby outputting the display data processed by the data processing circuit 101 to the panel signal channels.

In this embodiment, the data processing circuit 101, shift register 110, driving control circuit 120, timing controller 130, data receiving interface 140, and data output interface 150 can be hardware circuits with data processing, storage, and control capabilities. For example, the data processing circuit 101 can be an Application Specific Integrated Circuit (ASIC); the shift register 110 can be Static Random Access Memory (SRAM); the driving control circuit 120 and timing controller 130 can be Field Programmable Gate Array (FPGA) or Complex Programmable Logic Device (CPLD); while the data receiving interface 140 and data output interface 150 can be standardized serial or parallel communication interface circuits.

In another embodiment, the timing controller 130 can also implement driving timing compensation function. Specifically, the timing controller 130 can apply appropriate delay time to specific channel groups based on driving time differences between different channel groups, to ensure the continuity of overall driving timing. This compensation mechanism can effectively prevent non-uniform phenomena in the display screen.

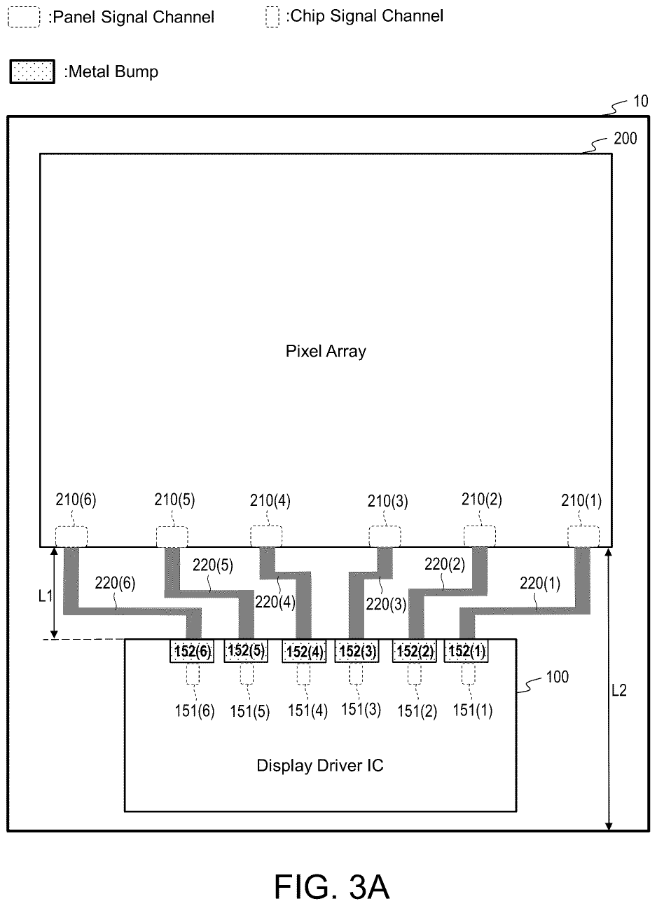

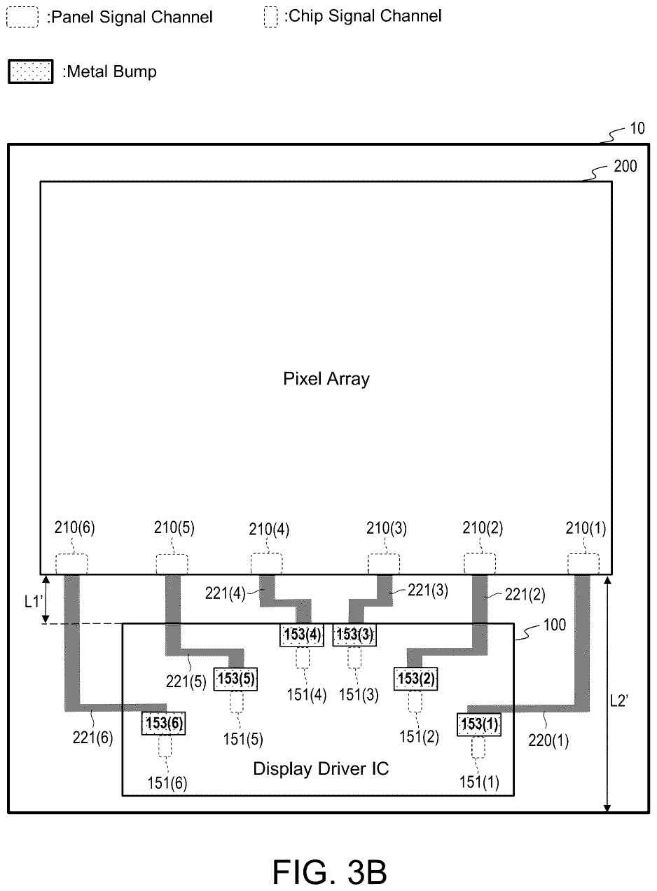

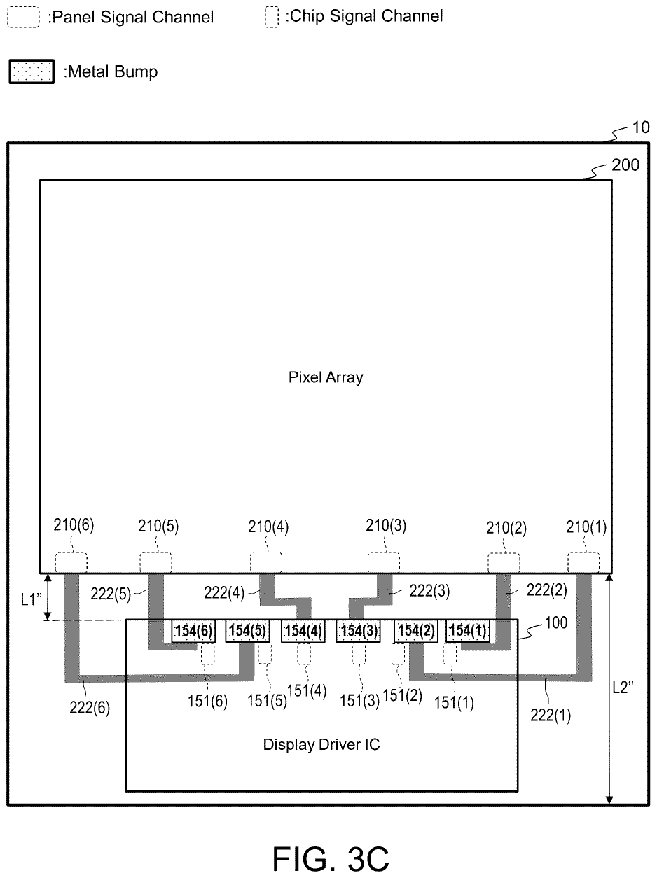

FIG. 3A is a schematic diagram illustrating a wiring layout of a traditional display module. Referring to FIG. 3A, a traditional wiring configuration of the display module 10 is presented. The display module 10 includes a display driver 100 and a pixel array 200, wherein the display driver 100 adopts traditional wiring layout method to drive the pixel array 200.

For example, assuming the display driver 100 has a plurality of chip signal channels 151(1) to 151(6), and corresponding metal bumps 152(1) to 152(6) are disposed thereon. These metal bumps 152(1) to 152(6) are respectively electrically connected to panel signal channels 210(1) to 210(6) of the pixel array 200 through source lines 220(1) to 220(6). In this traditional configuration, the source lines 220(1) to 220(6) adopt direct corresponding connection method, that is, the first chip signal channel 151(1) connects to the first panel signal channel 210(1), the second chip signal channel 151(2) connects to the second panel signal channel 210(2), and so forth.

It should be particularly noted that in this application, source lines 220(1) to 220(6) are conductors in the fan-out region, extended from source lines (or data lines) within the pixel array 200, and electrically connected to corresponding metal bumps. Panel signal channels refer to source lines within the pixel array 200 and all pixel units connected to these source lines. Chip signal channels refer to data channel circuits in the display driver 100 for transmitting display signals to source lines in the pixel array, including metal wires, ESD protection units, amplifiers, digital-to-analog converters, etc. In an embodiment, source lines 220(1) to 220(6) are generated in the same manner as circuits within the pixel array 200.

Under this traditional wiring layout, since each source line 220(1) to 220(6) needs to maintain certain spacing to avoid signal interference, a relatively wide border region is formed between the display driver 100 and the pixel array 200. As shown in the figure, the spacing L1 between the pixel array 200 and the display driver 100, due to the limitations of line manufacturing process, cannot be shortened, thereby leading to the width L2 of the display module's border needing to be above a certain length (wider bezel). Although this layout method is simpler in process, it is not conducive to achieving slim bezel design, especially in vehicle display applications, where it may affect overall visual effect and installation flexibility.

FIG. 3B is a schematic diagram illustrating a wiring layout of a display module with recessed bump design.

Referring to FIG. 3B, another approach is using an improved display module 10. The display module 10 includes a display driver 100 and a pixel array 200, wherein the display driver 100 adopts recessed metal bump design to achieve slim bezel effect.

For example, assuming the display driver 100 has a plurality of chip signal channels 151(1) to 151(6), and corresponding metal bumps 153(1) to 153(6) are disposed thereon. These metal bumps 153(1) to 153(6) are respectively electrically connected to panel signal channels 210(1) to 210(6) of the pixel array 200 through source lines 221(1) to 221(6). In this improved configuration, the metal bumps 153(1) to 153(6) adopt recessed design (or can be called inward-retracted design), making their positions extend from the chip edge toward the interior.

In this recessed design, the routing paths of source lines 221(1) to 221(6) can more effectively utilize the area within the boundary of the display driver 100. Since part of the connection paths are moved to the area within the chip boundary, the spacing L1′ between the display driver 100 and the pixel array 200 can be reduced, thereby achieving narrower border width L2′. However, although this design method can achieve slim bezel effect, it requires an additional metal layer in the chip interior for fan-out connection of recessed metal bumps 153(1) to 153(6), thus reducing the metal layer resources available for other purposes.

On the other hand, the recessed metal bump design requires special process to achieve bump structures of different depths, which increases process complexity. Furthermore, due to the adoption of special bump structure, driver ICs with this design cannot share the same process with driver ICs using traditional bump structure, leading to the need for additional part number management, which increases the complexity of production management.

FIG. 3C is a schematic diagram illustrating a wiring layout of a display module according to an embodiment of the present disclosure.

Referring to FIG. 3C, in an embodiment, the present disclosure provides an improved display module 10, which includes a display driver 100 and a pixel array 200. The display driver 100 adopts innovative signal channel grouping and wiring configuration to achieve slim bezel design.

Specifically, the display driver 100 has a plurality of chip signal channels 151(1) to 151(6), and corresponding metal bumps 154(1) to 154(6) are disposed thereon. These metal bumps 154(1) to 154(6) are respectively electrically connected to panel signal channels 210(1) to 210(6) of the pixel array 200 through source lines 222(1) to 222(6). However, different from traditional configuration, the present disclosure divides the plurality of chip signal channels 151(1) to 151(6) into multiple groups and adopts different connection patterns for different groups. As shown in FIG. 3C, source lines 222(1), 222(2), 222(5), and 222(6) have overlapping portions with the display driver 100, which can reduce spacing L1″.

In the example of FIG. 3C, the chip signal channels can be divided into two categories: the first category (also called, first chip signal channel group) includes chip signal channels 151(3) to 151(4) corresponding to panel signal channels 210(3) to 210(4), adopting forward connection (also called, first connection pattern); the second category (also called, second chip signal channel group) such as chip signal channels 151(1) to 151(2) and chip signal channels 151(5) to 151(6) corresponding to panel signal channels 210(1) to 210(2) and panel signal channels 210(5) to 210(6), adopting reverse connection (also called, second connection pattern).

More specifically, in the first chip signal channel group corresponding to the first connection pattern, chip signal channel 151(3) connects to panel signal channel 210(3) through source line 222(3), chip signal channel 151(4) connects to panel signal channel 210(4) through source line 222(4), connecting in corresponding number order.

In the second chip signal channel group (such as chip signal channels 151(1) to 151(2) corresponding to panel signal channels 210(1) to 210(2)) corresponding to the second connection pattern, chip signal channel 151(1) connects to panel signal channel 210(2) through source line 222(2) and chip signal channel 151(2) connects to panel signal channel 210(1) through source line 222(1), showing an opposite connection pattern in the order of connected numbers.

More specifically, in an embodiment, the data processing circuit 101 divides all chip signal channels into two groups: first chip signal channel group and second chip signal channel group. Among them, the first chip signal channel group contains N channels, while the second chip signal channel group contains M channels; correspondingly, the panel also has corresponding first panel signal channel group and second panel signal channel group set up, containing N and M panel signal channels respectively.

For the first connection pattern, this embodiment adopts direct sequential mapping method, namely:

Each (i+1)th chip signal channel in each first chip signal channel group (where i is from 0 to N−1) directly connects to the (i+1)th panel signal channel in the corresponding first panel signal channel group.

For example, assuming there are 4 channels in the first chip signal channel group (i.e., N=4), then the mapping relationship is:

The 1st chip signal channel connects to the 1st panel signal channel in the first panel signal channel group; the 2nd chip signal channel connects to the 2nd panel signal channel; the 3rd chip signal channel connects to the 3rd panel signal channel; the 4th chip signal channel connects to the 4th panel signal channel.

For the second connection pattern, this embodiment adopts reverse order mapping method, namely:

Each (M−j)th chip signal channel in each second chip signal channel group (where j is from 0 to M−1) connects to the (j+1)th panel signal channel in the corresponding second panel signal channel group.

For example, assuming there are 3 channels in the second chip signal channel group (i.e., M=3), then the mapping relationship is: when j=0, the (3−0)=3rd chip signal channel connects to the (0+1)=1st panel signal channel in the second panel signal channel group; when j=1, the (3−1)=2nd chip signal channel connects to the (1+1)=2nd panel signal channel in the second panel signal channel group; when j=2, the (3−2)=1st chip signal channel connects to the (2+1)=3rd panel signal channel in the second panel signal channel group.

Through the specific implementation of these two connection patterns, this embodiment can achieve precise adjustment of data transmission in different regions, where the first chip signal channel group maintains forward consistency with the first panel signal channel group, while the second chip signal channel group adopts reverse connection strategy to better adapt to panel wiring layout and driving timing compensation requirements. This mapping method helps ensure correct and continuous driving of panel sub-pixels under slim bezel design, thereby achieving the purpose of improving display effect and uniformity.

Through this innovative grouping and connection configuration, the routing of source lines 220(1) to 220(6) can more effectively utilize the area of the display driver 100. This design allows the spacing L1″ between the display driver 100 and the pixel array 200 to be significantly reduced, thereby achieving narrower border width L2″. Compared with traditional configuration, the present disclosure does not need to use recessed metal bumps, therefore requiring no additional metal layer resources, and can be compatible with standard processes.

This improved design also has advantages in production management. Since it adopts standard metal bump structure, the same driver IC can be applied to products with both traditional bezel and slim bezel, greatly simplifying product part number management. Furthermore, through control of data filling order, it can ensure display signals correctly correspond to target pixel positions, maintaining display quality.

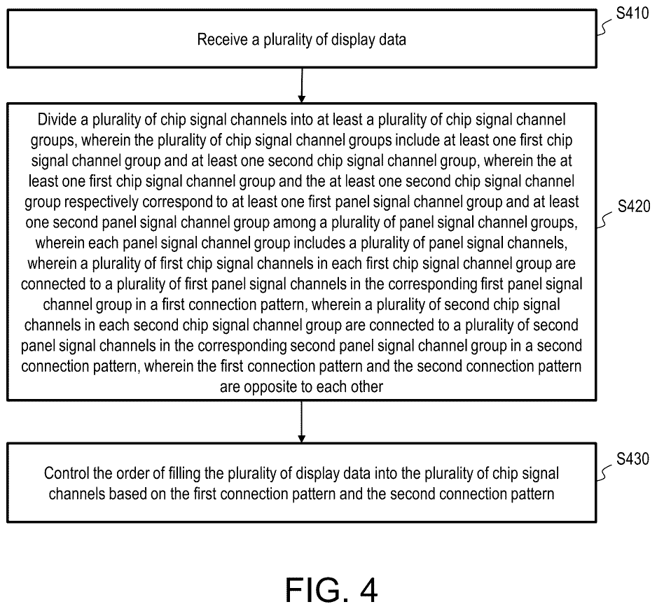

FIG. 4 is a flowchart illustrating a signal channel grouping and data processing method according to an embodiment of the present disclosure.

Referring to FIG. 4, in an embodiment, the present disclosure provides a signal channel grouping and data processing method. The method includes the following steps: step S410, step S420, and step S430.

In step S410, the data processing circuit of the display driver 100 receives a plurality of display data. The display data is used for driving the pixel array 200 of the display module 10 to display corresponding image content.

In step S420, the data processing circuit groups the plurality of chip signal channels of the display driver 100. Specifically, the plurality of chip signal channels are divided into at least one first chip signal channel group and at least one second chip signal channel group. Each chip signal channel group respectively corresponds to specific panel signal channel groups of the pixel array 200. Each panel signal channel group includes a plurality of panel signal channels.

In step S420, each first chip signal channel group's plurality of first chip signal channels adopts a first connection pattern to connect to the plurality of first panel signal channels in the corresponding first panel signal channel group. Conversely, each second chip signal channel group's plurality of second chip signal channels adopts a second connection pattern to connect to the plurality of second panel signal channels in the corresponding second panel signal channel group. It is worth noting that the first connection pattern and the second connection pattern are opposite connection methods.

In step S430, the data processing circuit controls the order of filling the plurality of display data into the plurality of chip signal channels based on the first connection pattern and the second connection pattern. Through this control of data filling order, it ensures display data can correctly correspond to target pixel positions.

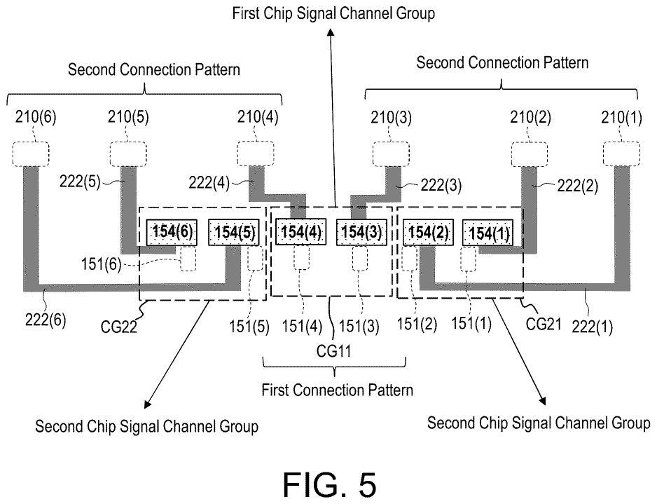

FIG. 5 is a schematic diagram illustrating connection patterns between chip signal channels and panel signal channels according to an embodiment of the present disclosure.

Referring to FIG. 5, in an embodiment, the present disclosure presents an optimized channel connection configuration. For example, to achieve slim bezel design, the plurality of chip signal channels 151(1) to 151(6) of the display driver 100 are divided into multiple chip signal channel groups and adopt different connection patterns to correspond to panel signal channels 210(1) to 210(6) (using 6 signal channels as a simple example for illustration).

Specifically, the plurality of chip signal channel groups include: a first chip signal channel group CG11, which contains chip signal channels 151(3) to 151(4); and two second chip signal channel groups CG21 and CG22, where CG21 contains chip signal channels 151(1) to 151(2), and CG22 contains chip signal channels 151(5) to 151(6). These chip signal channel groups are respectively electrically connected to panel signal channels 210(1) to 210(6) through their corresponding metal bumps 154(1) to 154(6) and source lines 222(1) to 222(6).

In the first chip signal channel group CG11, the first connection pattern is adopted, maintaining forward connection order. For example, chip signal channel 151(3) connects to panel signal channel 210(3) through source line 222(3), chip signal channel 151(4) connects to panel signal channel 210(4) through source line 220(4), showing a sequential corresponding connection method.

Conversely, in the second chip signal channel groups CG21 and CG22, the second connection pattern is adopted, using reverse connection order. Taking CG21 as an example, chip signal channel 151(1) connects to panel signal channel 210(2) through source line 222(2), chip signal channel 151(2) connects to panel signal channel 210(1) through source line 222(1); similarly, CG22 also adopts a similar reverse connection method.

Through this special grouping and connection configuration, the present disclosure can achieve slim bezel effect equivalent to recessed bump design without changing metal bump structure. This design not only avoids additional metal layer resource consumption but also maintains compatibility with standard processes.

Another advantage of this connection configuration is its flexibility. By adjusting the number of channel groups and the size of each group, the border width can be optimized according to different application requirements. Furthermore, since standard metal bump structure is adopted, the same driver IC design can be used in products with different bezel requirements.

It should be understood that the connection configuration of the present disclosure is not limited to the three chip signal channel groups shown in this embodiment. According to actual hardware specifications, application requirements, and design considerations, the chip signal channels can be divided into more groups, and the number of channels in each group can also be adjusted according to specific situations to achieve optimal border width optimization and other performance indicators.

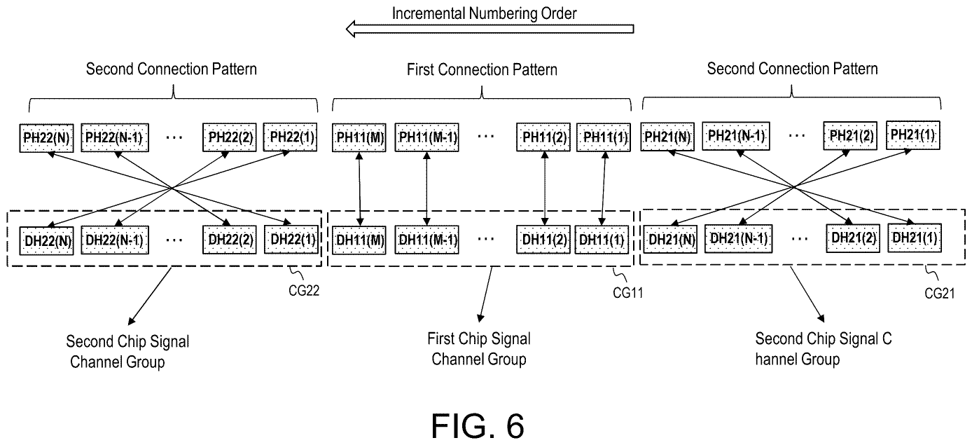

FIG. 6 is a schematic diagram illustrating a first type of data filling order according to an embodiment of the present disclosure.

Referring to FIG. 6, in an embodiment, the present disclosure provides an incremental numbering order data filling configuration. The figure shows the grouping of chip signal channels in the display driver 100 and their corresponding data transmission paths.

Specifically, the plurality of chip signal channels are divided into three signal channel groups: first chip signal channel group CG11, second chip signal channel groups CG21 and CG22. The channels in the first chip signal channel group CG11 maintain the first connection pattern, where data from PH11(1) to PH11(M) respectively connect to DH11(1) to DH11(M). This connection configuration indicates that in the first chip signal channel group CG11, the data filling order maintains consistency with the physical order of channels.

Conversely, in the second chip signal channel groups CG21 and CG22, the second connection pattern is adopted, showing reverse connection order. Taking CG21 as an example, data from PH21(1) to PH21(N) respectively connect to DH21(N) to DH21(1), exhibiting a reverse correspondence relationship. Similarly, in CG22, data from PH22(1) to PH22(N) also adopt the same reverse connection method, connecting to DH22(N) to DH22(1).

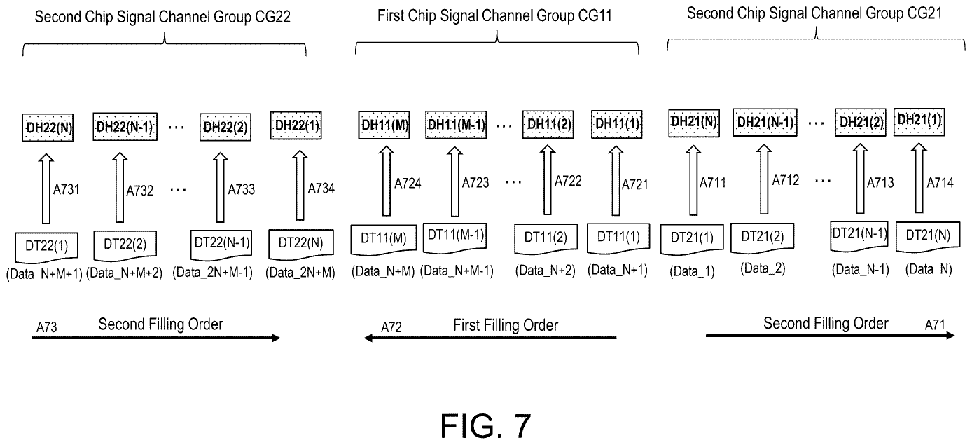

FIG. 7 is a schematic diagram illustrating a second type of data filling order according to an embodiment of the present disclosure.

Referring to FIG. 7, in an embodiment, the present disclosure provides a data filling mechanism used to control the filling order of display data in different chip signal channel groups.

Specifically, the display driver 100 adopts different filling orders according to different chip signal channel groups. For the second chip signal channel group CG21, the second filling order A71 shown by arrows A711 to A714 is adopted. Under this filling order, N pieces of display data DT21(1) to DT21(N) corresponding to the second chip signal channel group CG21 among the received display data Data_1 to Data_2N+M will be filled in reverse order into chip signal channels DH21(N) to DH21(1) according to the second filling order. For example, as shown by arrow A711, display data DT21(1) is filled into chip signal channel DH21(N); as shown by arrow A712, display data DT21(2) is filled into chip signal channel DH21(N−1); and so on, as shown by arrow A713, display data DT21(N−1) is filled into chip signal channel DH21(2); as shown by arrow A714, display data DT21(N) is filled into chip signal channel DH21(1).

For the first chip signal channel group CG11, the first filling order A72 shown by arrows A721 to A724 is adopted. Under this filling order, M pieces of display data DT11(1) to DT11(M) corresponding to the first chip signal channel group CG11 among the received display data Data_1 to Data_2N+M will be filled sequentially into chip signal channels DH11(1) to DH11(M) according to the first filling order. For example, as shown by arrow A721, display data DT11(1) is filled into chip signal channel DH11(1); as shown by arrow A722, display data DT11(2) is filled into chip signal channel DH11(2); and so on, as shown by arrow A723, display data DT11(M−1) is filled into chip signal channel DH11(M−1); as shown by arrow A724, display data DT11(M) is filled into chip signal channel DH11(M).

Similar to the second chip signal channel group CG21, for the second chip signal channel group CG22, the second filling order A73 shown by arrows A731 to A734 is adopted. Under this filling order, N pieces of display data DT22(1) to DT22(N) corresponding to the second chip signal channel group CG22 among the received display data Data_1 to Data_2N+M will be filled in reverse order into chip signal channels DH22(N) to DH22(1) according to the second filling order.

In an embodiment, the timing controller 130 is configured to preprocess the plurality of display data before they are input to the plurality of chip signal channels. During the preprocessing, the timing controller 130 will identify the plurality of second display data corresponding to each second chip signal channel group and adjust the arrangement order of these second display data.

For example, when the plurality of display data includes N pieces of second display data corresponding to the second chip signal channel group CG21, the timing controller 130 will perform reverse sorting operation on these N pieces of second display data. Specifically, the timing controller 130 will adjust the original first piece of second display data to become the Nth piece of adjusted second display data, adjust the original second piece of second display data to become the (N−1)th piece of adjusted second display data, and so on, until adjusting the original Nth piece of second display data to become the first piece of adjusted second display data.

After the timing controller 130 completes the data sorting adjustment, it will transmit the adjusted second display data to the driving control circuit 120. The driving control circuit 120 then fills these adjusted second display data into corresponding chip signal channels according to preset filling order.

Through this preprocessing mechanism, the display driver 100 can complete necessary data sorting adjustment before data is actually filled into chip signal channels, storing all data in the data queue (or corresponding register), using general data filling order to fill all display data in the data queue into corresponding signal channels. Furthermore, since the sorting adjustment operation is completed before data filling, it can avoid performing complex real-time adjustments during the filling process, thereby improving overall processing efficiency.

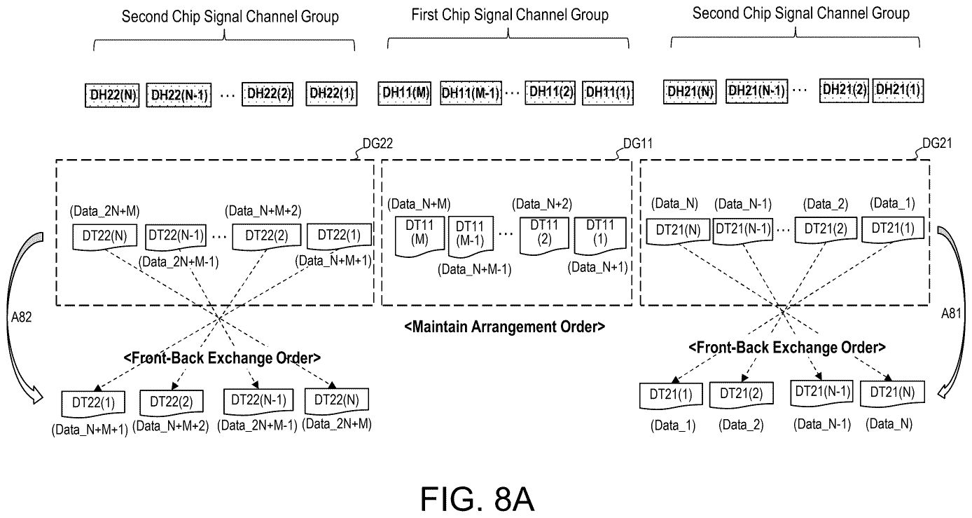

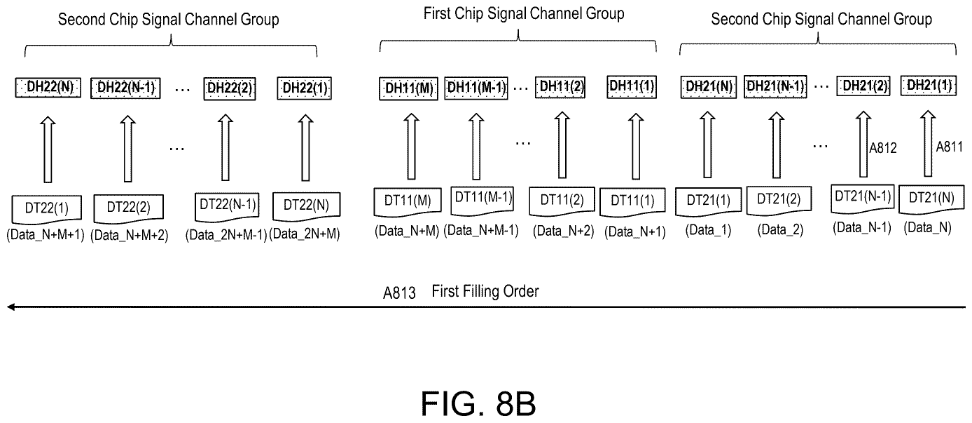

FIG. 8A is a schematic diagram illustrating a front-back exchange order for multiple chip signal channel groups according to an embodiment of the present disclosure.

Referring to FIG. 8A, in an embodiment, the present disclosure provides a display data exchange method. The display driver 100 divides display data corresponding to different chip signal channel groups into multiple display data groups DG11, DG21, and DG22, and adopts specific data processing strategies for specific display data groups.

Specifically, for display data group DG11 corresponding to the first chip signal channel group, a maintain arrangement order strategy is adopted, ensuring that data in the first chip signal channel group maintains its original order.

For display data group DG21 corresponding to the second chip signal channel group CG21, as shown by arrow A81, a front-back exchange order strategy is adopted. Under this strategy, display data DT21(1) to DT21(N) undergo order exchange. For example, the original display data ordered from DT21(1) to DT21(N) will become ordered from DT21(N) to DT21(1) after adjustment.

Similarly, for display data group DG22 corresponding to the second chip signal channel group CG22, as shown by arrow A82, a front-back exchange order strategy is also adopted. Under this strategy, display data DT22(1) to DT22(N) undergo order exchange. For example, the original display data ordered from DT22(1) to DT22(N) will become ordered from DT22(N) to DT22(1) after adjustment.

FIG. 8B is a schematic diagram illustrating a data filling order according to an embodiment of the present disclosure.

Referring to FIG. 8B, in another embodiment, the present disclosure provides a simplified data filling mechanism. In this embodiment, the driving control circuit 120 adopts a unified first filling order A83 to process all display data, including both adjusted second display data and unadjusted first display data.

Specifically, after the timing controller 130 completes the reverse sorting adjustment of second display data, the driving control circuit 120 can adopt a single forward filling order to process all display data. As shown in FIG. 8B, this forward filling order means: as shown by arrows A811, A812 . . . , the adjusted second display data DT21(N) to DT21(1), first display data DT11(1) to DT11(M), adjusted second display data DT22(N) to DT22(1) are sequentially filled into multiple chip signal channels DH21(1) to DH21(N) of the second chip signal channel group, multiple chip signal channels DH11(1) to DH11(M) of the first chip signal channel group, multiple chip signal channels DH22(1) to DH22(N) of the second chip signal channel group.

Since their corresponding display data has already been reverse-sorted by the timing controller 130, even with forward filling, the required reverse connection effect can still be maintained. For the first chip signal channel group, since its corresponding display data needs no adjustment, forward filling can maintain the required forward connection effect.

By adopting this unified filling order, this embodiment greatly simplifies the implementation complexity of the data filling mechanism. Furthermore, since the data sorting adjustment work has been completed by the timing controller 130 in advance, the driving control circuit 120 only needs to execute a single type of filling operation, thereby enhancing system stability and reliability.

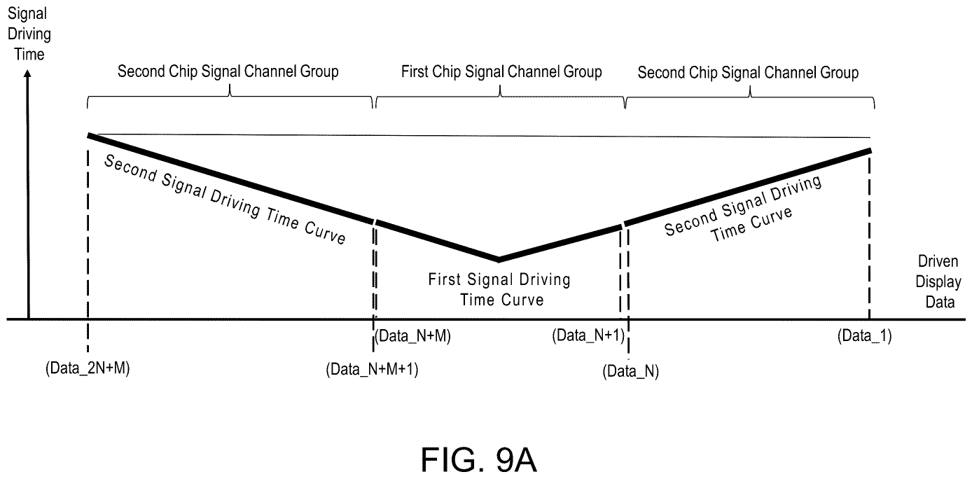

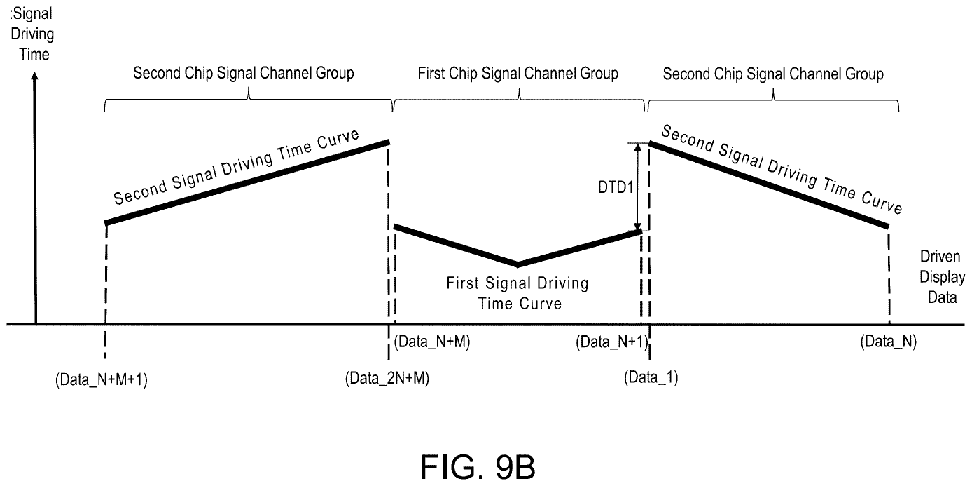

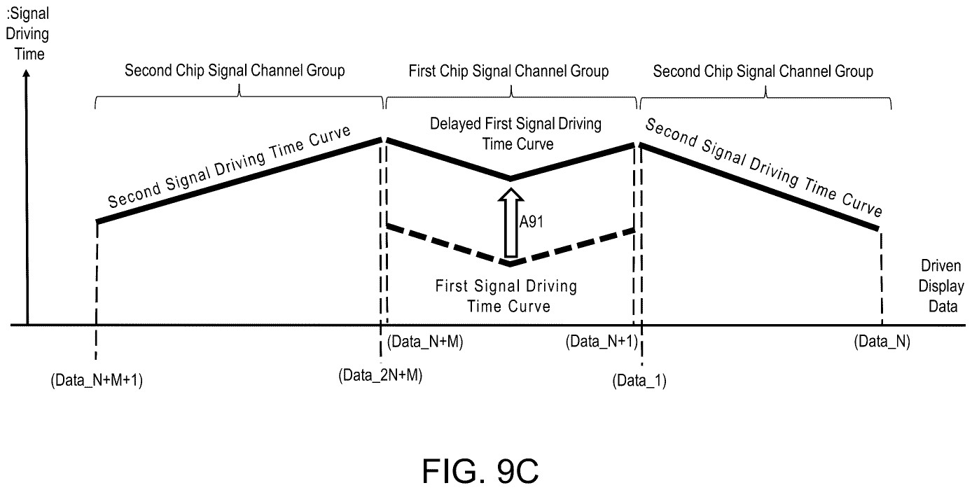

FIG. 9A is a schematic diagram illustrating traditional signal driving time curves.

Referring to FIG. 9A, traditional display driving method's signal driving time curves are presented. The signal driving time curves demonstrate the timing characteristics of different chip signal channel groups when driving display data.

Specifically, the signal driving time curves include: second signal driving time curve corresponding to the second chip signal channel group, first signal driving time curve corresponding to the first chip signal channel group, and second signal driving time curve corresponding to another second chip signal channel group. The horizontal axis represents the driven display data, from Data_2N+M to Data_1; the vertical axis represents the driving time needed for signals to reach target values.

Due to the physical characteristics of the display driver 100, chip signal channels located at the chip center position have shorter signal transmission paths, thus their driving time is shorter. Conversely, chip signal channels located at chip edge positions, due to having longer signal transmission paths, their driving time is relatively longer. Therefore, the signal driving time curves present a characteristic curve that is lowest at the chip center and gradually rises toward both sides.

Through this traditional driving time curve configuration, the driving time differences between adjacent channels show continuous and smooth changes. This continuity helps avoid sudden brightness changes appearing in the display screen, thereby ensuring the uniformity of overall display quality. However, when adopting new slim bezel design, due to the need to change channel connection configuration, this continuity might be affected, therefore an appropriate compensation mechanism needs to be adopted.

In this embodiment, the driving control circuit 120 of the display driver 100 is designed to adjust the driving timing of each chip signal channel group to achieve continuity in display data output. Specifically, after the chip signal channels are divided into first chip signal channel group and second chip signal channel group, the driving control circuit first applies a preset delay time to each first chip signal channel group. The purpose of this delay is to shift all first signals' (first display data) driving time curves backward in time, thereby forming continuous driving timing with adjacent second chip signal channel group's second signals (second display data). In this mechanism, by appropriately delaying the driving time of first signals in the first chip signal channel group, their output waveforms precisely align on the time axis with the driving waveforms of second signals in the immediately adjacent second chip signal channel group. In other words, although the two groups of channels may have differences in transmission delay or driving speed, after delay adjustment, the first group of signals seamlessly connects with the second group of signals in time, forming a continuous and smooth driving timing, ensuring the brightness and color consistency and uniformity of the display screen.

In another embodiment, to further enhance the flexibility and stability of delay adjustment, the driving control circuit 120 also includes a preset delay time level selection module. This preset delay time level selection module provides multiple fixed delay time levels, with each level corresponding to a preset delay value. When the timing difference detection module measures the time difference between the first signal driving time curve of the first chip signal channel group and the second signal driving time curve of the adjacent second chip signal channel group, the control logic will automatically select corresponding fixed delay value from the delay time levels based on which range the difference falls into. Subsequently, this fixed delay value is applied to all first display data output from the first chip signal channel group to adjust their driving time curves. This mechanism of adjustment through preset delay time levels can quickly and stably respond to various environmental conditions (such as temperature changes or power supply fluctuations) causing timing changes, further ensuring that first and second signal driving time curves can approximately seamlessly connect, thereby achieving continuous and uniform display effect.

The above delay compensation mechanism ensures that after data is input to chip signal channels, the driving timing between channels achieves continuous and uniform effect, thereby avoiding display issues such as uneven brightness, color distortion, etc. that might be caused by timing discontinuity. Ultimately, through this method, the display driver 100 can achieve high-quality and uniform display effect while meeting slim bezel design requirements.

FIG. 9B is a schematic diagram illustrating the measurement of signal driving time differences according to an embodiment of the present disclosure.

Referring to FIG. 9B, an uncompensated driving timing state is presented. Due to the special channel grouping and connection configuration adopted by the present disclosure, without timing compensation, obvious discontinuities appear between the driving time curves of different chip signal channel groups.

Specifically, there exists a driving time difference DTD1 between the first signal driving time curve of the first chip signal channel group and the second signal driving time curve of the adjacent second chip signal channel group. This driving time difference DTD1 is particularly evident at the boundary between consecutively filled display data Data_1 and Data_N+1, where Data_N+1 corresponds to the first chip signal channel group while Data_1 corresponds to the adjacent second chip signal channel group.

This driving time discontinuity mainly originates from the special channel grouping configuration adopted by the present disclosure. Specifically, when the chip signal channels of the first chip signal channel group adopt the first connection pattern while the adjacent second chip signal channel group adopts the second connection pattern, not only do these chip signal channels have different signal transmission path lengths due to their different physical locations on the chip, but they may also be affected by other structural factors such as panel signal channel physical addresses and source line lengths. These factors work together to cause differences in channel driving times, thereby leading to driving timing discontinuity.

If this driving time difference DTD1 is not compensated, it may cause obvious brightness differences at the boundaries between different channel groups in the display screen. For example, when Data_1's driving time is shorter than Data_N+1's driving time, it may cause sudden changes in corresponding pixel brightness, affecting overall display quality. Therefore, appropriate delay compensation mechanism needs to be adopted to eliminate this driving timing discontinuity.

FIG. 9C is a schematic diagram illustrating signal driving time curves after delay compensation according to an embodiment of the present disclosure.

Referring to FIG. 9C, in an embodiment, the present disclosure provides a driving timing compensation mechanism, wherein the driving control circuit 120 adjusts the first signal driving time curve into a delayed first signal driving time curve by applying appropriate delay time A91.

Specifically, as shown by arrow A91, the delayed first signal driving time curve is achieved by applying delay time to the driving timing of the first chip signal channel group. The magnitude of delay time can be determined based on the previously detected driving time difference DTD1. Through this delay compensation mechanism, the first signal driving time curve is shifted upward, thereby eliminating timing discontinuity with the adjacent second signal driving time curve.

In this improved driving timing configuration, the delayed first signal driving time curve and its adjacent second signal driving time curves can form continuous transitions at the boundaries between Data_N+M and Data_2N+M, as well as between Data_1 and Data_N+1. This continuous smooth driving timing characteristic not only eliminates the original driving time difference but also ensures the uniformity of the overall display screen.

Through this driving timing compensation mechanism, it solves the timing discontinuity problem that may occur when adopting special channel grouping configuration, thereby maintaining good display quality while achieving slim bezel design.

Based on the above, the display driver and display module provided by the present disclosure can achieve slim bezel effect while avoiding additional metal layer resource consumption by dividing multiple chip signal channels into multiple chip signal channel groups and adopting opposite connection patterns. Specifically, the solution of the present disclosure does not need to use recessed bumps for fan-out routing, thereby preserving complete metal layer resources and improving the routing flexibility of the chip. Furthermore, through the special design of the data processing circuit, the present disclosure achieves flexible control over the filling order of display data. This control mechanism ensures that display data can correctly correspond to target pixel positions under different connection patterns, thereby maintaining display quality. In particular, since the present disclosure adopts a standard bump structure, the same driver IC can be applied to products with both traditional bezel and slim bezel, significantly simplifying product part number management and improving production efficiency. Meanwhile, through precise control of driving timing and delay compensation mechanism, the present disclosure effectively solves the driving timing discontinuity problem between different channel groups, ensuring the uniformity of the display screen.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display driver to drive a pixel array of a display module, the display driver comprising:
a plurality of metal bumps, disposed at a first boundary of the display driver, wherein the plurality of metal bumps respectively correspond to a plurality of chip signal channels of the display driver, and the plurality of metal bumps are respectively electrically connected to a plurality of panel signal channels of the pixel array through a plurality of source lines;
a data processing circuit to receive a plurality of display data, and divide the plurality of chip signal channels into a plurality of chip signal channel groups wherein the data processing circuit is further configured to divide the plurality of chip signal channels into a plurality of chip signal channel groups, the plurality of chip signal channel groups include at least one first chip signal channel group and at least one second chip signal channel group,
wherein the at least one first chip signal channel group and the at least one second chip signal channel group respectively correspond to at least one first panel signal channel group and at least one second panel signal channel group among a plurality of panel signal channel groups, wherein each panel signal channel group includes a plurality of panel signal channels,
wherein a plurality of first chip signal channels in each first chip signal channel group are connected to a plurality of first panel signal channels in the corresponding first panel signal channel group in a first connection pattern,
wherein a plurality of second chip signal channels in each second chip signal channel group are connected to a plurality of second panel signal channels in the corresponding second panel signal channel group in a second connection pattern, wherein the first connection pattern and the second connection pattern are opposite to each other,
wherein the data processing circuit is further configured to control an order of filling the plurality of display data into the plurality of chip signal channels based on the first connection pattern and the second connection pattern.

2. The display driver as claimed in claim 1, wherein the first connection pattern refers to that an (i+1)th first chip signal channel in each first chip signal channel group is connected to an (i+1)th first panel signal channel in the corresponding first panel signal channel group, wherein i is an integer from 0 to N−1, and N is a total number of the plurality of first chip signal channels in the first chip signal channel group,
wherein the second connection pattern refers to that an (M−j)th second chip signal channel in each second chip signal channel group is connected to a (j+1)th second panel signal channel in the corresponding second panel signal channel group, wherein j is an integer from 0 to M−1, and M is a total number of the plurality of second chip signal channels in the second chip signal channel group.

3. The display driver as claimed in claim 2, wherein the data processing circuit comprises:
a shift register, configured to temporarily store the plurality of display data; and
a driving control circuit, electrically connected to the shift register, configured to control filling the plurality of display data from the shift register into the plurality of chip signal channels based on the first connection pattern and the second connection pattern.

4. The display driver as claimed in claim 3, wherein the driving control circuit is further configured to:
sequentially fill N pieces of first display data corresponding to each first chip signal channel group into a first to an Nth first chip signal channel in the first chip signal channel group; and
sequentially fill M pieces of second display data corresponding to each second chip signal channel group into an Mth to a first second chip signal channel in the second chip signal channel group.

5. The display driver as claimed in claim 3, wherein the data processing circuit further comprises:
a timing controller, electrically connected to the driving control circuit, configured to:
adjust an arrangement order of M pieces of second display data corresponding to each second chip signal channel group before the plurality of display data are input to the plurality of chip signal channels.

6. The display driver as claimed in claim 5, wherein the timing controller is further configured to:
perform reverse sorting on the M pieces of second display data from a first to an Mth piece of second display data among the M pieces of second display data corresponding to each second chip signal channel group, so as to obtain M pieces of adjusted second display data.

7. The display driver as claimed in claim 6, wherein the driving control circuit is further configured to:
sequentially fill N pieces of first display data corresponding to each first chip signal channel group into a first to an Nth first chip signal channel in the first chip signal channel group; and
sequentially fill the M pieces of adjusted second display data corresponding to each second chip signal channel group into a first to an Mth second chip signal channel in the second chip signal channel group.

8. The display driver as claimed in claim 1, wherein the display module has a glass substrate, and the pixel array and the plurality of source lines are formed on the glass substrate.

9. The display driver as claimed in claim 3, wherein the driving control circuit is further configured to:
apply a delay time to each first chip signal channel group, so as to form a continuous driving timing between a first signal driving time curve of the first chip signal channel group and a second signal driving time curve of an adjacent second chip signal channel group.

10. The display driver as claimed in claim 9, wherein the driving control circuit is further configured to:
detect a signal driving time difference between the first signal driving time curve of the first chip signal channel group and the second signal driving time curve of the adjacent second chip signal channel group; and
according to the signal driving time difference, apply the delay time to a plurality of first display data output by the plurality of first chip signal channels of the first chip signal channel group, so as to form a continuous driving timing between a delayed first signal driving time curve and the second signal driving time curve.

11. A display module, comprising:
a pixel array;
a plurality of panel signal channels, formed on a glass substrate, wherein the pixel array is electrically connected to the plurality of panel signal channels; and
a display driver, comprising:
a plurality of metal bumps, disposed at a first boundary of the display driver, wherein the plurality of metal bumps respectively correspond to a plurality of chip signal channels of the display driver, and the plurality of metal bumps are respectively electrically connected to the plurality of panel signal channels through a plurality of source lines; and
a data processing circuit, configured to receive a plurality of display data,
wherein the data processing circuit is further configured to divide the plurality of chip signal channels into at least a plurality of chip signal channel groups, the plurality of chip signal channel groups include at least one first chip signal channel group and at least one second chip signal channel group,
wherein the at least one first chip signal channel group and the at least one second chip signal channel group respectively correspond to at least one first panel signal channel group and at least one second panel signal channel group among a plurality of panel signal channel groups, wherein each panel signal channel group includes a plurality of panel signal channels,
wherein a plurality of first chip signal channels in each first chip signal channel group are connected to a plurality of first panel signal channels in the corresponding first panel signal channel group in a first connection pattern,
wherein a plurality of second chip signal channels in each second chip signal channel group are connected to a plurality of second panel signal channels in the corresponding second panel signal channel group in a second connection pattern, wherein the first connection pattern and the second connection pattern are opposite to each other,
wherein the data processing circuit is further configured to control an order of filling the plurality of display data into the plurality of chip signal channels based on the first connection pattern and the second connection pattern.

12. The display module as claimed in claim 11, wherein the first connection pattern refers to that an (i+1)th first chip signal channel in each first chip signal channel group is connected to an (i+1)th first panel signal channel in the corresponding first panel signal channel group, wherein i is an integer from 0 to N−1, and N is a total number of the plurality of first chip signal channels in the first chip signal channel group,
wherein the second connection pattern refers to that an (M−j)th second chip signal channel in each second chip signal channel group is connected to a (j+1)th second panel signal channel in the corresponding second panel signal channel group, wherein j is an integer from 0 to M−1, and M is a total number of the plurality of second chip signal channels in the second chip signal channel group.

13. The display module as claimed in claim 12, wherein the data processing circuit comprises:
a shift register, configured to temporarily store the plurality of display data; and
a driving control circuit, electrically connected to the shift register, configured to control filling the plurality of display data from the shift register into the plurality of chip signal channels based on the first connection pattern and the second connection pattern.

14. The display module as claimed in claim 13, wherein the driving control circuit is further configured to:
sequentially fill N pieces of first display data corresponding to each first chip signal channel group into a first to an Nth first chip signal channel in the first chip signal channel group; and
sequentially fill M pieces of second display data corresponding to each second chip signal channel group into an Mth to a first second chip signal channel in the second chip signal channel group.

15. The display module as claimed in claim 13, wherein the data processing circuit further comprises:
a timing controller, electrically connected to the driving control circuit, configured to:
adjust an arrangement order of M pieces of second display data corresponding to each second chip signal channel group before the plurality of display data are input to the plurality of chip signal channels.

16. The display module as claimed in claim 15, wherein the timing controller is further configured to:
perform reverse sorting on the M pieces of second display data from a first to an Mth piece of second display data among the M pieces of second display data corresponding to each second chip signal channel group, so as to obtain M pieces of adjusted second display data.

17. The display module as claimed in claim 16, wherein the driving control circuit is further configured to:
sequentially fill N pieces of first display data corresponding to each first chip signal channel group into a first to an Nth first chip signal channel in the first chip signal channel group; and
sequentially fill the M pieces of adjusted second display data corresponding to each second chip signal channel group into a first to an Mth second chip signal channel in the second chip signal channel group.

18. The display module as claimed in claim 11, wherein the plurality of source lines are formed on the glass substrate.

19. The display module as claimed in claim 13, wherein the driving control circuit is further configured to:
apply a delay time to each first chip signal channel group, so as to form a continuous driving timing between a first signal driving time curve of the first chip signal channel group and a second signal driving time curve of an adjacent second chip signal channel group.

20. The display module as claimed in claim 19, wherein the driving control circuit is further configured to:
detect a signal driving time difference between the first signal driving time curve of the first chip signal channel group and the second signal driving time curve of the adjacent second chip signal channel group; and
according to the signal driving time difference, apply the delay time to a plurality of first display data output by the plurality of first chip signal channels of the first chip signal channel group, so as to form a continuous driving timing between the first signal driving time curve and the second signal driving time curve.
